(19) United States
(12) Patent Application Publication
(10) Pub. No.: US 2023/0011846 A1
(43) Pub. Date: Jan. 12, 2023

(54) Low Voltage DC-DC Converter

(71) Applicants: Hyundai Motor Company, Seoul (KR); Kia Corporation, Seoul (KR)

(72) Inventors: Dae Woo Lee, Incheon (KR); Taejong Ha, Seoul (KR)

(21) Appl. No.: 17/809,338

(22) Filed: Jun. 28, 2022

(30) Foreign Application Priority Data
Jul. 6, 2021 (KR) 10-2021-0088687

(51) Int. Cl. H02M 3/335

(52) U.S. Cl. CPC H02M 3/335; H05K 7/209

(57) ABSTRACT

A low voltage converter includes a transformer controller configured to control at least one switch to supply a high voltage of a main battery to a transformer. The transformer is configured to convert the high voltage of the main battery to a low voltage. An output circuit is configured to output the low voltage to a load or a battery through a capacitor coupled in series with an inductor is provided.

### CROSS-REFERENCE TO RELATED APPLICATIONS

This application claims priority to and the benefit of Korean Patent Application No. 10-2021-0088687 filed in the Korean Intellectual Property Office on Jul. 6, 2021, the entire contents of which are incorporated herein by reference.

### TECHNICAL FIELD

This description relates to a low voltage DC-DC converter.

### BACKGROUND

Electric vehicles and hybrid vehicles use a DC/DC converter to supply power to 12V load of the vehicles and to charge a 12V battery. A low voltage DC/DC converter (LDC) is used as such a DC/DC converter.

The above information disclosed in this Background section is only for enhancement of understanding of the background of the invention, and therefore it may contain information that does not form the prior art that is already known in this country to a person of ordinary skill in the art.

### SUMMARY

Embodiments provide low voltage converters.

According to an embodiment, a low voltage converter is provided. In such an embodiment, the low voltage converter includes a transformer controller configured to control at least one switch to supply a high voltage of a main battery to a transformer. The transformer is configured to convert the high voltage of the main battery to a low voltage. An output circuit is configured to output the low voltage to a load or a battery through a capacitor coupled in series with an inductor. One of the inductor is coupled to the transformer and another end of the inductor is coupled to a ground coupled to a heat sink for heat dissipation.

In an embodiment, the transformer may include a tap configured to divide a secondary winding of the transformer into a first winding and a second winding.

In such an embodiment, when the transformer controller controls the at least one switch to supply the high voltage of the main battery to the transformer, the transformer may be configured to convert the high voltage of the main battery to the low voltage according to a first turns ratio between a primary winding of the transformer and the first winding of the secondary winding.

In such an embodiment, when the transformer controller controls the at least one switch to supply a voltage stored in a reset capacitor of the transformer controller to the transformer, the transformer may be configured to convert the voltage stored in the reset capacitor into the low voltage according to a second turns ratio between the primary winding of the transformer and the second winding of the secondary winding.

In an embodiment, the one end of the inductor may be coupled to the tap of the transformer.

In an embodiment, the low voltage converter may further include a rectifier configured to rectify a current by the converted low voltage, and one end of the capacitor may be coupled to the rectifier and another end of the capacitor may be coupled to the ground.

According to another embodiment, a low voltage converter is provided. In such an embodiment, the low voltage converter includes a transformer controller configured to control at least one switch to supply a high voltage of a main battery to a transformer. The transformer is configured to convert the high voltage of the main battery to a low voltage. A rectifier is configured to rectify a current by the converted low voltage. An output circuit is configured to transfer the rectified current to a load or a battery through a capacitor coupled in series with an inductor. One end of the inductor is coupled to the capacitor and another end of the inductor is coupled to a ground coupled to a heat sink for heat dissipation.

In an embodiment, the transformer may include a tap configured to divide a secondary winding of the transformer into a first winding and a second winding and the ground may be coupled with the tap of the transformer.

In an embodiment, one end of the capacitor may be coupled to the rectifier, another end of the capacitor may be coupled to the inductor, and a low voltage load and/or a low voltage battery may be coupled to both ends of the capacitor.

According to yet another embodiment, a low voltage converter is provided. In such an embodiment, the low voltage converter includes a transformer controller configured to control at least one switch to supply a high voltage of a main battery to a transformer. The transformer is configured to convert the high voltage of the main battery to a low voltage. An output circuit is configured to output the low voltage to a load or a battery through a capacitor coupled in series with an inductor. One end of the inductor is coupled to a tap that divides a secondary winding of the transformer into a first winding and a second winding and another end of the inductor is coupled to a ground coupled to a heat sink for heat dissipation.

### BRIEF DESCRIPTION OF THE DRAWINGS

For a more complete understanding of the present invention, reference is now made to the following descriptions taken in conjunction with the accompanying drawings, in which:

FIG. 1 is a block diagram illustrating an LDC according to an embodiment;

FIG. 2 is a circuit diagram illustrating an LDC according to an embodiment;

FIG. 3 is a circuit diagram illustrating an LDC according to another embodiment;

FIG. 4 is a circuit diagram illustrating an LDC according to yet another embodiment;

FIG. 5 is a diagram illustrating an LDC according to an embodiment;

FIG. 6 is a circuit diagram illustrating an LDC according to yet another embodiment; and

FIG. 7 is a circuit diagram illustrating an LDC according to another embodiment.

### DETAILED DESCRIPTION OF ILLUSTRATIVE EMBODIMENTS

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

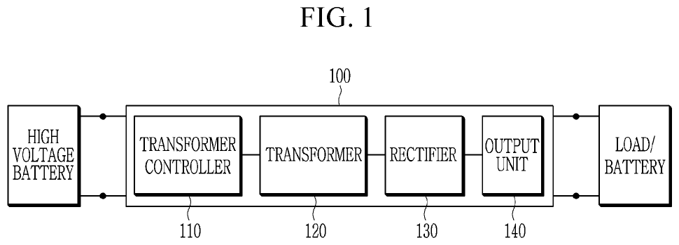

FIG. 1 is a block diagram illustrating an LDC according to an embodiment.

An LDC 100 according to an embodiment may convert a high voltage (e.g., 400V) of a main battery into a low voltage (e.g., 12V or 48V). For example, the LDC 100 may be used to convert the high voltage of the main battery of the electric vehicle into the low voltage. Therefore, the LDC 100 may supply power to a load that uses the low voltage and charge a low voltage battery (e.g., batteries for electronic equipment) of the vehicle. As the LDC 100, an active-clamp forward converter (ACF converter) may be used. The AFC may prevent saturation of a transformer by forming a discharge path for energy stored in an inductance of the transformer.

Referring to FIG. 1, a low voltage DC-DC converter (LDC) 100 according to an embodiment may include a transformer controller 110, a transformer 120, a rectifier 130, and an output circuit 140. The LDC 100 may convert the high voltage of the main battery to the low voltage and transfer the converted low voltage to a low voltage load and a low voltage battery.

Referring to FIG. 1, when the transformer controller 110 controls a plurality of switches to supply the high voltage Vᵢₙ of the main battery to the transformer 120, the high voltage Vᵢₙ of the main battery may be converted to the low voltage by the transformer 120 so that the converted low voltage is supplied to a secondary part of the transformer 120. The current caused by the low voltage formed on the secondary part of the transformer 120 may be rectified by the rectifier 130 and then may be transferred to the output circuit 140.

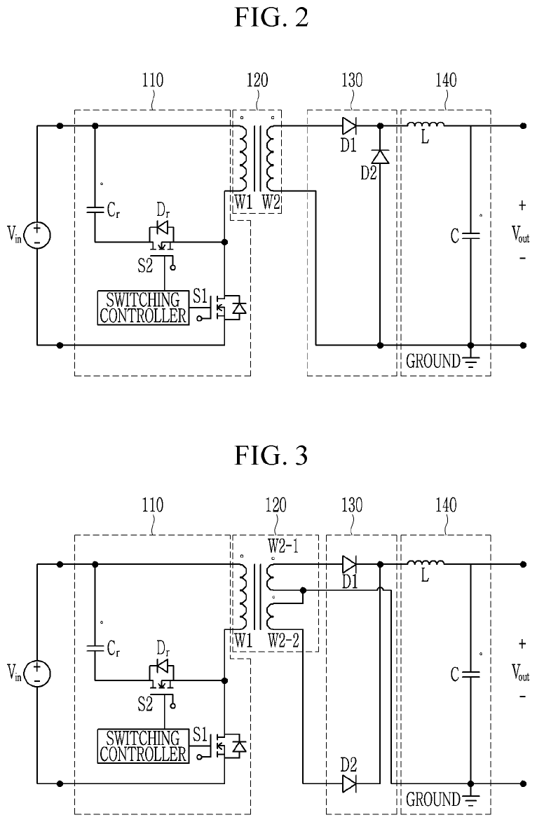

FIG. 2 is a circuit diagram illustrating an LDC 100 according to an embodiment.

The transformer controller 110 may include a first switch S1, a second switch S2, a reset capacitor Cᵣ, and a switching controller. The first switch S1 and the second switch S2 may be implemented as MOSFETs. The operation of the transformer 120 may be controlled according to the switching operation of the first switch S1 and the second switch S2.

In the LDC 100 according to an embodiment, the high voltage of the main battery may be supplied to the primary winding W1 during the ‘on’ period of the first switch S1 and the ‘off’ period of the second switch S2 so that the current flows in the primary winding W1. During this period, the current induced in the secondary winding W2 may be provided to the output circuit 140 through a first diode D1 of the rectifier 130.

After that, before the first switch S1 is turned off and the second switch S2 is turned on (turn-on), the energy of the primary winding W1 may be transferred to the reset capacitor Cᵣ through diodes Dᵣ coupled to both ends of the second switch S2. Next, when the second switch S2 is turned on in the off state of the first switch S1, the opposite direction current may flow to the primary winding W1 of the transformer 120 by the energy stored in the reset capacitor Cᵣ and the transformer 120 may be reset. That is, the saturation of the transformer may be prevented by resetting the transformer by the control of the switching controller of the transformer controller 110.

The rectifier 130 may include a first diode D1 and a second diode D2. The rectifier 130 may generate a DC voltage by rectifying the voltage and/or current transmitted to the secondary part of the transformer 120 using the first diode D1 and the second diode D2.

The output circuit 140 may provide the DC voltage rectified by the rectifier 130 to the low voltage load and/or the low voltage battery. The output circuit 140 may be an output filter including an inductor and a capacitor and the inductor and capacitor may be coupled in series.

Referring to FIG. 2, when the transformer 120 converts the high voltage Vᵢₙ of the main battery to the low voltage, the first diode D1 of the rectifier 130 may conduct and the rectified current may be transferred to the output circuit 140. Since the current due to the low voltage converted from the high voltage Vᵢₙ of the main battery may flow upward direction with respect to a surface of FIG. 2 in the secondary winding W2 of the transformer 120, the second diode D2 of the rectifier 130 may not conduct.

When the switching controller of the transformer controller 110 turns off the first switch S1, the energy of the primary winding W1 of the transformer 120 may be transferred to the reset capacitor Cᵣ through the diode Dᵣ coupled to both ends of the second switch S2. Then, when the second switch S2 is turned on while the first switch S1 is off, the transformer 120 may be reset since the current by the energy stored in the reset capacitor Cᵣ flows in the upward direction with respect to the surface of FIG. 2.

A charging cycle of the LDC 100 according to an embodiment may include ‘first switch on and second switch off step→first switch off and second switch off step→first switch off and second switch on step’ and so on. In the LDC 100 according to an embodiment, the energy of the main battery may be transferred to the secondary portion of the transformer 120 once during one cycle by the control of the transformer controller 110.

FIG. 3 is a circuit diagram illustrating an LDC according to another embodiment.

Referring to FIG. 3, the secondary winding of the transformer 120 may be divided into a first winding W2-1 and a second winding W2-2 by a tap.

When the switching controller of the transformer controller 110 turns on the first switch S1, the high voltage Vᵢₙ of the main battery may be transferred to the transformer 120, and then the high voltage Vᵢₙ of the main battery may be converted to a low voltage according to a turns ratio between the primary winding W1 of the transformer 120 and the first winding W2-1 of the secondary portion and may be supplied to the secondary part of the transformer 120. The current by the low voltage generated on the upper side of the transformer 120 may be rectified by the first diode D1 of the rectifier 130 and then transferred to the output circuit 140.

Since the current caused by the low voltage generated on the upper side of the transformer 120 flows on the winding W2-1 of the secondary part of the transformer 120 in the upward direction with respect to the surface of FIG. 3, the current may be transmitted to the inductor L of the output circuit 140 after passing through the first diode D1 of the rectifier 130.

Then, when the switching controller of the transformer controller 110 turns off the first switch S1, the energy of the primary winding W1 of the transformer 120 may be transferred to the reset capacitor Cᵣ through the diode Dᵣ coupled to both ends of the second switch S2. After that, when the switching controller turns on the second switch S2, the current flows on the primary winding W1 by the energy stored in the reset capacitor Cᵣ. That is, the energy stored in the reset capacitor Cᵣ may be converted into a low voltage according to the turns ratio of the primary winding W1 of the transformer 120 and the second winding W2-2 of the secondary part, and be transferred to the secondary part of the transformer 120. The current due to the low voltage generated on the lower side of the transformer 120 may be rectified by the second diode D2 of the rectifier and then transferred to the output circuit 140.

Since the current caused by the low voltage generated on the lower side of the transformer 120 flows at the winding W2-2 of the secondary part of the transformer 120 in the downward direction with respect to the surface of FIG. 3, the current may be transferred to the inductor L of the output circuit 140 after passing through the second diode D2 of the rectifier 130.

That is, the LDC 100 according to another embodiment may transfer the high voltage of the main battery to the secondary part of the transformer 120 twice during one cycle under the control of the transformer controller 110.

However, at this time, since the high current is transferred to the output circuit 140, a large amount of heat may be generated in the inductor L of the output circuit 140. Therefore, the LDC 100 according to another embodiment may require an additional heat dissipation structure to dissipate the heat of the inductor L to the outside.

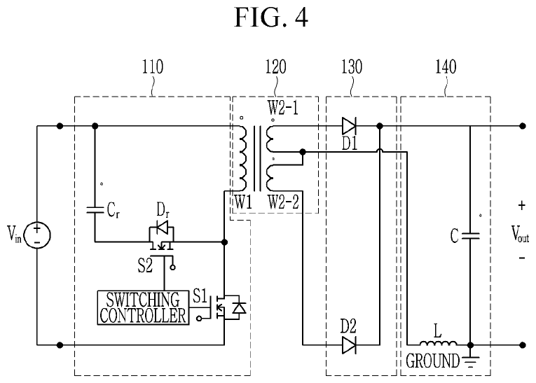

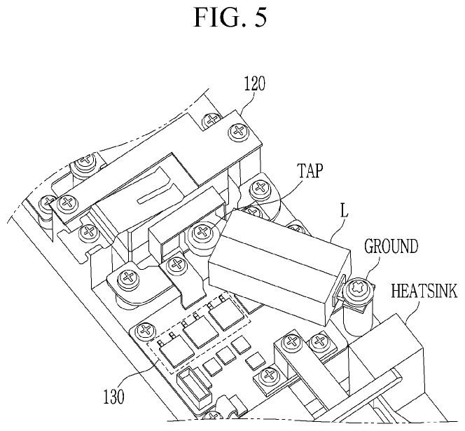

FIG. 4 is a circuit diagram illustrating an LDC according to yet another embodiment and FIG. 5 is a diagram illustrating an LDC according to another embodiment.

Referring to FIG. 4 and FIG. 5, when the switching controller of the transformer controller 110 turns on the first switch S1, the high voltage Vᵢₙ of the main battery may be transferred to the transformer 120 and then, the high voltage Vᵢₙ of the main battery may be converted to a low voltage according to the turns ratio of the primary winding W1 of the transformer 120 and the first winding W2-1 of the secondary part to be supplied to the secondary part of the transformer 120. The current caused by the low voltage generated on the upper side of the transformer 120 may be rectified by the first diode D1 of the rectifier 130 and then transferred to the output circuit 140. The current passing through the first diode D1 of the rectifier 130 from the upper side of the transformer 120 may be transferred to the capacitor C of the output circuit 140 and may be directed to the tap of the transformer 120 via the inductor L.

Then, when the switching controller of the transformer controller 110 turns off the first switch S1, the energy of the primary winding W1 of the transformer 120 may be transferred to the reset capacitor Cᵣ through the diode Dᵣ coupled to both ends of the second switch S2. After that, when the switching controller turns on the second switch S2, the voltage by the energy stored in the reset capacitor Cᵣ may be supplied to both ends of the transformer 120. The energy stored in the reset capacitor Cᵣ may be converted to a low voltage according to the turns ratio of the primary winding W1 of the transformer 120 and the second winding W2-2 of the secondary part and the converted low voltage may be transferred to the secondary part of the transformer 120. The current by the low voltage generated on the lower side of the transformer 120 may be rectified by the second diode D2 of the rectifier and then transferred to the output circuit 140. The current passing through the second diode of the rectifier 130 from the lower side of the transformer 120 may be transferred to the capacitor C of the output circuit 140, and then may be directed to the tap of the transformer 120 via the inductor L.

Referring to FIG. 4 and FIG. 5, one end of the inductor L of the output circuit 140 may be coupled to the tap of the transformer 120, and the other end of the inductor L may be directly coupled to the ground. That is, since the inductor L of the output circuit 140 of the LDC 100 according to another embodiment is directly coupled to the ground that is coupled to the heatsink, the heat dissipation performance of the LDC 100 can be improved without a heat dissipation component.

FIG. 5 illustrates a possible physical configuration of a portion of the LDC 100. As shown, the transformer 120 and the rectifier 130 are disposed on an upper surface of the substrate. The inductor L extends from the heat sink over the rectifier 130 to the transformer 120.

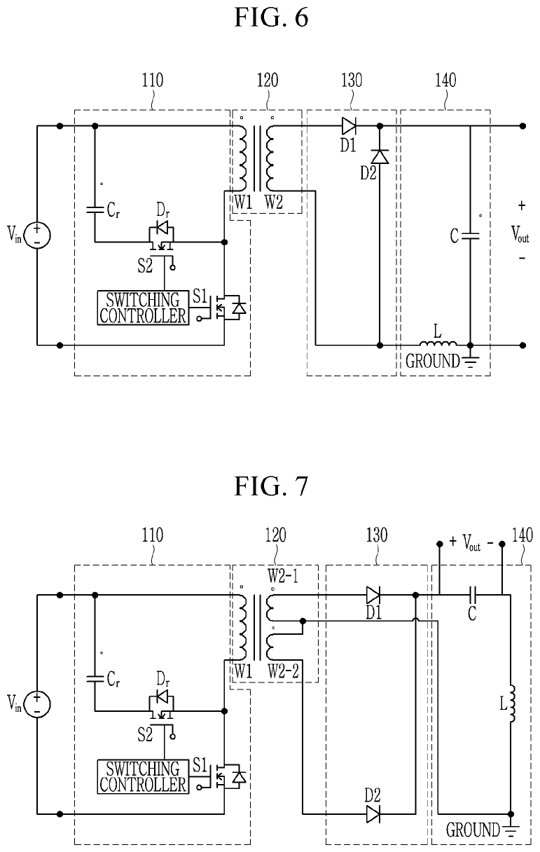

FIG. 6 is a circuit diagram illustrating an LDC according to yet another embodiment.

Referring to FIG. 6, when the switching controller of transformer controller 110 turns on the first switch S1, the high voltage Vᵢₙ of the main battery is supplied to the transformer 120, and the transformer 120 converts the high voltage Vᵢₙ of the main battery to a low voltage, the first diode D1 of the rectifier 130 may conduct and the current by the rectified low voltage may be transferred to one end of the capacitor C of the output circuit 140.

One end of the inductor L of the output circuit 140 may be coupled to the rectifier 130 and the other end of the inductor L may be directly coupled to the ground, so that the heat generated by the high current flowing the inductor L can be quickly dissipated through the heat sink coupled to the ground.

FIG. 7 is a circuit diagram illustrating an LDC according to another embodiment.

Referring to FIG. 7, when the switching controller of the transformer controller 110 turns on the first switch S1, the high voltage Vᵢₙ of the main battery may be supplied to the transformer 120. Then, the high voltage Vᵢₙ of the main battery may be converted to a low voltage according to the turns ratio between the first winding W2-1 of the secondary part and the primary winding W1 of the transformer 120 and the converted low voltage may be formed on the secondary part of the transformer 120. The current by the low voltage generated on the upper side of the transformer 120 may be rectified by the first diode D1 of the rectifier 130 and then the rectified current may be transferred to the output circuit 140.

Since the current caused by the low voltage formed on the upper side of the transformer 120 flows at the winding W2-1 of the secondary part of the transformer 120 in the upward direction with respect to the surface of FIG. 7, the current may pass through the first diode D1 of the rectifier 130 and then be transferred to the capacitor C of the output circuit 140.

When the switching controller of the transformer controller 110 turns off the first switch S1, the energy of the primary winding W1 of the transformer 120 may be stored in the reset capacitor Cᵣ through the diode Dᵣ at both ends of the second switch S2. When the switching controller turns on the second switch S2, the voltage by the energy stored in the reset capacitor Cᵣ may be supplied to both ends of the transformer 120. The voltage by the energy stored in the reset capacitor Cᵣ may be converted to a low voltage according to the turns ratio between the primary winding W1 of the transformer 120 and the second winding W2-2 of the secondary part and the converted low voltage may be formed on the secondary part of the transformer 120. The current caused by the low voltage formed on the lower side of the transformer 120 may be rectified by the second diode D2 of the rectifier and then transferred to the output circuit 140.

Since the current caused by the low voltage formed on the lower side of the transformer 120 flows at the winding W2-2 of the secondary part of the transformer 120 in the downward direction with respect to the surface of FIG. 7, the current may pass through the second diode D2 of the rectifier 130 and then transferred to the capacitor C of the output circuit 140.

Because one end of the inductor L of the output circuit 140 is coupled to the capacitor C and the other end of the inductor L is directly coupled to the ground, the heat generated by the high current on the inductor L can be quickly dissipated through the heat sink coupled to the ground.

As described above, since the inductor L of the output circuit 140 of the LDC 100 is directly coupled to the ground that is joined to the heat sink, improvement of the heat dissipation performance by the heat sink can be expected without additional heat dissipation components. That is, the heat generated by the high current transferred to the output filter of the LDC can be dissipated to the outside of the LDC without the addition of the heat dissipation components.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A low voltage converter, comprising:
a transformer controller configured to control at least one switch to supply a high voltage of a main battery to a transformer;
the transformer configured to convert the high voltage of the main battery to a low voltage; and
an output circuit configured to output the low voltage to a load or a battery through a capacitor coupled in series with an inductor, wherein one end of the inductor is coupled to the transformer and another end of the inductor is coupled to a ground node.

2. The low voltage converter of claim 1, further comprising a heat sink coupled to the ground node at the other end of the inductor.

3. The low voltage converter of claim 1, wherein:
the transformer comprises a tap configured to divide a secondary winding of the transformer into a first winding and a second winding;
when the transformer controller controls the at least one switch to supply the high voltage of the main battery to the transformer, the transformer is configured to convert the high voltage of the main battery to the low voltage according to a first turns ratio between a primary winding of the transformer and the first winding of the secondary winding; and
when the transformer controller controls the at least one switch to supply a voltage stored in a reset capacitor of the transformer controller to the transformer, the transformer is configured to convert the voltage stored in the reset capacitor into the low voltage according to a second turns ratio between the primary winding of the transformer and the second winding of the secondary winding.

4. The low voltage converter of claim 3, wherein the one end of the inductor is coupled to the tap of the transformer.

5. The low voltage converter of claim 4, further comprising a rectifier configured to rectify a current by the converted low voltage, wherein one end of the capacitor is coupled to the rectifier and another end of the capacitor is coupled to the ground node.

6. The low voltage converter of claim 1, wherein the one end of the inductor is coupled to a tap that divides a secondary winding of the transformer into a first winding and a second winding.

7. A low voltage converter, comprising:
a transformer controller configured to control at least one switch to supply a high voltage of a main battery to a transformer;
the transformer configured to convert the high voltage of the main battery to a low voltage;
a rectifier configured to rectify a current by the converted low voltage; and
an output unit configured to transfer the rectified current to a load or a battery through a capacitor coupled in series with an inductor, wherein one end of the inductor is coupled to the capacitor and another end of the inductor is coupled to a ground node coupled to a heat sink.

8. The low voltage converter of claim 7, wherein the transformer comprises a tap configured to divide a secondary winding of the transformer into a first winding and a second winding and the ground node is coupled with the tap of the transformer.

9. The low voltage converter of claim 7, wherein one end of the capacitor is coupled to the rectifier, another end of the capacitor is coupled to the inductor, and a low voltage load or a low voltage battery is coupled to both ends of the capacitor.

10. A device comprising:
a transformer controller;
a transformer having a primary winding coupled the transformer controller;
a rectifier coupled to a secondary winding of the transformer;
an inductor having a first terminal coupled to the secondary winding of the transformer and a second terminal coupled to a ground node; and
a capacitor having a first terminal coupled to the rectifier and a second terminal coupled to the inductor.

11. The device of claim 10, wherein the second terminal of the capacitor is coupled to the second terminal of the inductor.

12. The device of claim 11, wherein the first terminal of the inductor is coupled to a tap divides the secondary winding of the transformer into a first winding and a second winding.

13. The device of claim 10, wherein the second terminal of the capacitor is coupled to the first terminal of the inductor.

14. The device of claim 13, wherein the first terminal of the inductor is coupled to a tap divides the secondary winding of the transformer into a first winding and a second winding.

15. The device of claim 10, further comprising a heat sink coupled to the ground node at the second terminal of the inductor.

16. The device of claim 15, further comprising a substrate, wherein the transformer and the rectifier are disposed on an upper surface of the substrate and wherein the inductor extends from the heat sink over the rectifier to the transformer.

17. The device of claim 10, further comprising:
a high voltage battery coupled to an input of the transformer controller; and
a load coupled to a differential output taken between the first terminal of the capacitor and the second terminal of the capacitor.

18. The device of claim 17, wherein the load comprises a low voltage battery.

19. The device of claim 10, wherein the transformer controller comprises:
a reset capacitor having a first terminal coupled to a first terminal of the primary winding;
a first switch having a current path coupled between a second terminal of the reset capacitor and a second terminal of the primary winding;
a second switch having a current path terminal coupled to the second terminal of the primary winding; and
a switching controller coupled to control terminals of the first and second switches.

20. The device of claim 10, wherein the rectifier comprises:
a first diode with a first terminal coupled to a first terminal of the secondary winding and a second terminal coupled to the first terminal of the capacitor; and
a second diode with a second terminal coupled to a second terminal of the secondary winding and a first terminal coupled to the first terminal of the capacitor.
